(19) United States
(12) Patent Application Publication
(10) Pub. No.: US 2009/0207463 A1
(43) Pub. Date: Aug. 20, 2009

(54) SCREEN DISPLAY CONTROL DEVICE

(75) Inventor: Michio YOSHITAKE, Fukuoka (JP)

Correspondence Address: EDWARDS ANGELL PALMER & DODGE LLP, P.O. BOX 55874, BOSTON, MA, 02205, US

(73) Assignee: Seiko Epson Corporation, Tokyo (JP)

(21) Appl. No.: 12/371,990

(22) Filed: Feb. 17, 2009

(30) Foreign Application Priority Data
Feb. 15, 2008 (JP) 2008-033919
Jun. 2, 2008 (JP) 2008-144247

(51) Int. Cl. G03F 3/10; G06K 9/36

(52) U.S. Cl. 358/527; 382/232

(57) ABSTRACT

A screen display control device includes: a compression unit which compresses input image data of a one-screen base image; a rewritable image memory to which the compressed data compressed by the compression unit is written in non-synchronization with a reading process; a decompression unit which decompresses the compressed data periodically read from the image memory in synchronization with screen display to restore original image data; a display unit which displays an image of the image data decompressed and restored by the decompression unit; a partial writing data storage unit which maintains partial writing data of a partial image to be displayed on the display unit by replacing a part of the base image; and a data replacement control unit which replaces a portion corresponding to the partial image in the image data of the base image restored by the decompression unit with the partial writing data to output the partial writing data to the compression unit.

### BACKGROUND

1. Technical Field

The present invention relates to a technique capable of controlling screen display.

2. Related Art

In the past, a screen display control device having a function of processing image data was known. The screen display control device generally includes an image memory (Video RAM) temporarily storing the processed image data and performs screen display by periodically reading the processed image data stored in the image memory. In recent years, however, a screen display apparatus such as a liquid crystal display, a plasma display, or an organic EL display has a capability to realize high definition and high gray scale, thereby increasing a volume of image data to be displayed in the screen display apparatus. Therefore, the image memory storing the increased volume of image data needs to have a large capacity, thereby causing an increase in manufacture cost. In order to solve this problem, a technique capable of compressing the image data by a known data compression method such as a predictive encoding (DPCM encoding) method of encoding differences of adjacent pixel data and storing the compressed data in the image memory was suggested (for example, see JP-A-2006-157806 (paragraphs 0014 to 0016, FIG. 18, etc.)). In addition, upon performing screen display, original image data are restored by reading the compressed data from the image memory and decompressing the compressed data. That is, by replacing the compressed data stored in the image memory with compressed data of a new image, it is possible to switch an image to be displayed.

However, the screen display control device compresses the image data using the differences of adjacent pixel data. Therefore, when some of the compressed data are rewritten, original image data are not restored and thus the compressed data stored in the image memory are not partially rewritable. For that reason, when a part of an image stored as the compressed data in the image memory is replaced with a partial image such as an icon, the entire image data in which the part of the image is replaced with the partial image as well as partial writing data of a partial image are necessary. That is, it is difficult to replace the part of the image with the partial image using only the partial writing data of the partial image, thereby causing very poor efficiency.

### SUMMARY

An advantage of some aspects of the invention is that it provides a technique capable of efficiently performing a partial writing process on image data.

According to an aspect of the invention, there is provided a screen display control device including: a compression unit which compresses input image data of a one-screen base image; a rewritable image memory to which the compressed data compressed by the compression unit is written in non-synchronization with a reading process; a decompression unit which decompresses the compressed data periodically read from the image memory in synchronization with screen display to restore original image data; a display unit which displays an image of the image data decompressed and restored by the decompression unit; a partial writing data storage unit which maintains partial writing data of a partial image to be displayed on the display unit by replacing a part of the base image; and a data replacement control unit which replaces a portion corresponding to the partial image in the image data of the base image restored by the decompression unit with the partial writing data to output the partial writing data to the compression unit.

In the screen display control device according to this aspect of the invention, after the portion corresponding to the partial image in the image data of the base image read from the image memory and restored by the decompression unit with the partial writing data is replaced with the partial writing data by the data replacement control unit, the partial writing data are compressed by the compression unit, and the compressed partial writing data are stored to the image memory. When the compressed data of which some are replaced with the partial writing data are read from the image memory and restored by the compression unit, an image in which the part of the base image is replaced with the partial image is displayed on the display unit. Therefore, since the image data are partially rewritable with only the partial writing data by using the image data of the base image obtained by decompressing the compressed data in the image memory, it is possible to replace the part of the base image with the partial image very efficiently.

In the screen display control device, the compression unit may compress the input image data in a line unit, the decompression unit may decompress and restore the compressed data periodically read from the image memory in the line unit in synchronization with screen display, and the data replacement control unit may replace the image data of the base image restored by the decompression unit with the partial writing data in the line unit to output the partial writing data to the compression unit. With such a configuration, it is possible to realize the processes in a simple manner by dividing a large volume of image data into data of a line unit.

The screen display control device may further include a setting unit which maintains coordinate information on a relative location with respect to the base image of the partial image. The data replacement control unit may includes: an area determiner which determines whether pixel data constituting the restored image data are replaced with the partial writing data on the basis of the coordinate information input from the setting unit; and a data selector which selects data to be output to the compression unit from one of the restored image data and the partial writing data depending on a result determined by the area determiner. With such a configuration, the area determiner determines whether the pixel data constituting the image data are replaced with the partial writing data on the basis of the coordinate information maintained in the setting unit. The data selector selects the data to be output to the compression unit from one of the restored image data and partial writing data depending on the determination result. Therefore, it is possible to exactly replace a portion corresponding to the partial image in the image data of the base image with the partial writing data.

### BRIEF DESCRIPTION OF THE DRAWINGS

The invention will be described with reference to the accompanying drawings, wherein like numbers reference like elements.

FIG. 1 is a perspective view illustrating a photo printer equipped with a screen display control device according to the invention.

FIG. 2 is a diagram illustrating an overall internal configuration of the photo printer.

FIG. 3 is a block diagram illustrating a configuration example of a controller.

FIG. 4 is a conceptual diagram illustrating a partial rewriting of image data.

FIG. 5 is a diagram illustrating an example of a reading process.

FIG. 6 is a diagram illustrating an example of a partial rewriting process.

FIG. 7 is a diagram illustrating another example of the configuration of the controller.

### DESCRIPTION OF EXEMPLARY EMBODIMENTS

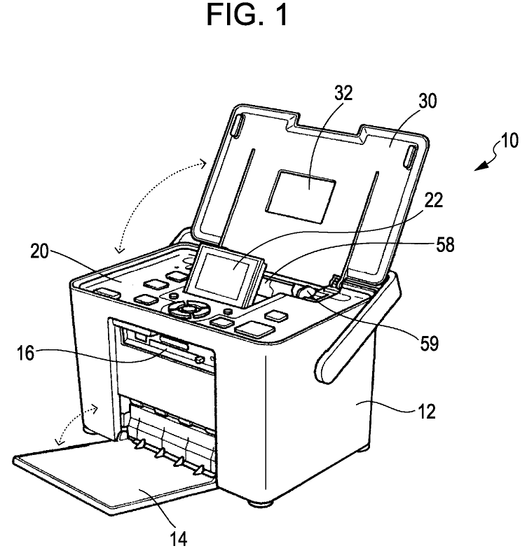

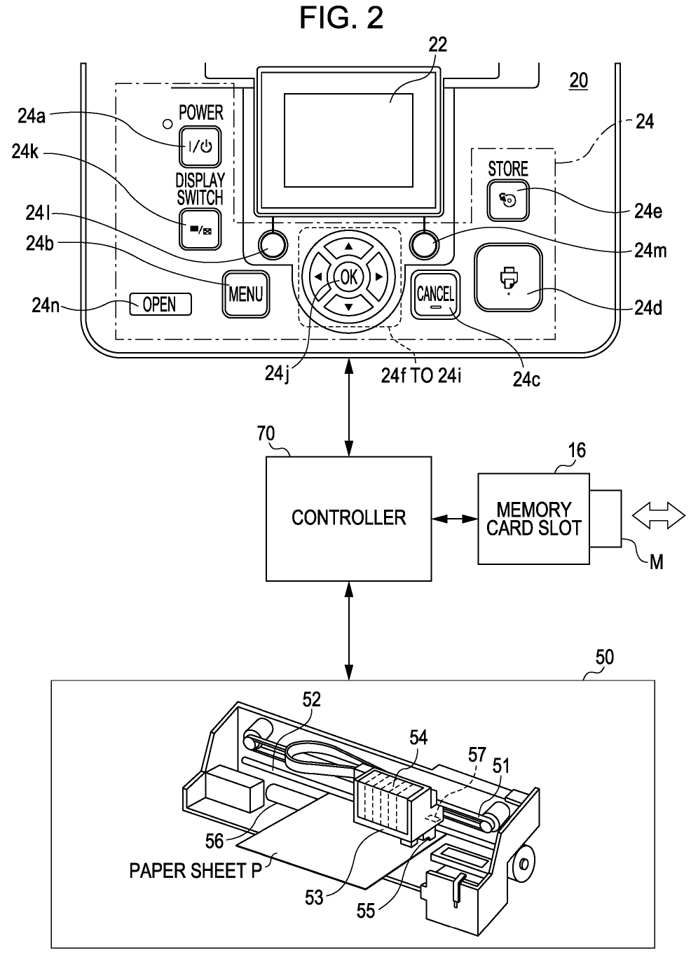

FIG. 1 is a perspective view illustrating a photo printer equipped with an LCD controller 76, which is an example of a screen display control device according to the invention. FIG. 2 is a diagram illustrating an overall internal configuration of the photo printer. A photo printer 10 has a printing mechanism 50 (see FIG. 2) inside a printer body 12 and prints an image on a paper sheet P in accordance with an operation command from a controller 70 (see FIG. 2) which controls the photo printer 10 on the whole. In addition, the printed paper sheet is discharged to a front surface of the printer body 12.

A front door 14 is openably mounted on the front surface of the printer body 12, as shown in FIG. 1. The front door 14 is a cover used to open and close the front surface of the printer body 12. When the front door 14 is opened, the front door 14 functions as a sheet discharging tray which receives the paper sheet P discharged from the print mechanism 50. In addition, a user is able to use various types of a memory card slot 16 formed on the front surface of the printer body 12. That is, when the front door 14 is opened, the user is able to insert a memory card M storing an image file, which is a printing target, into the memory card slot 16. An external medium storing an image file is not limited to the memory card, but may be a USB memory, a disk medium, or the like. An electronic apparatus such as a digital camera or a cellular phone storing images is connected to the photo printer 10 through a cable or infrared rays to function as the external medium.

An operational panel 20 is provided on the upper surface of the printer body 12 and a cover 30 is openably mounted on one side inside the upper surface of the printer body 12. The cover 30 is a resin plate formed with a size covering the upper surface of the printer body 12 and the surface of the operational panel 20 is exposed to the outside (see FIG. 1). On the other hand, when the cover 30 is closed, the cover 30 covers the entire operational panel 20.

The operational panel 20 includes a display unit 22 which is configured by as an LCD display displaying texts, figures, symbols, and the like and a group of buttons 24 arranged around the display unit 22. As shown in FIG. 2, the group of buttons 24 includes: a power button 24a used to turn on and off a power source; a menu button 24b used to allow a main menu to be displayed on a screen; a cancel button 24c used to cancel an operation during performing the operation or interrupt a printing process on the paper sheet P during the printing process; a print button 24d used to instruct a print execution onto the paper sheet P; a store button 24e used to store an edited image to the memory card M inserted into the memory card slot 16; upper, lower, right, and left arrow buttons 24f to 24i used to select a desired option among plural options displayed on the display unit 22, used to move a cursor, or for other operations; an OK button 24j disposed in the center of the upper, lower, right, and left arrow buttons 24f to 24i and used to instruct the option selected by the arrow buttons 24f to 24i; a display switch button 24k used to switch screen display on the display unit 22; a left guide selection button 241 used to select a left guide displayed on the display unit 22; a right guide selection button 24m used to select a right guide displayed on the display unit 22; and a sheet discharging tray opening button 24n used to open the front door 14 functioning as a sheet discharging tray.

In order to confirm display details of the display unit 22, a window 32 having the same size as that of the display unit 22 is provided in the cover 30. That is, when the cover 30 is closed, the user is able to confirm the display details of the display unit 22 through the window 32. On the other hand, when the cover 30 is opened, the display unit 22 is configured so as to adjust a desired angle as shown in FIG. 1.

When the cover 30 is opened, the cover 30 is configured so as to be inclined toward the rear side with respect to the operational panel 20 to be maintained and used as a tray supplying the paper sheet P to the printing mechanism 50. Inside the operational panel 20, a sheet feeding port 58 of the printing mechanism 50 is provided and a pair of sheet guides 59 operated in a slide manner in right and left direction so that a guide width is matched with the width of the paper sheet are also provided.

The paper sheet P is fed to the printing mechanism 50 through the sheet feeding port 58 to perform the printing process. As shown in FIG. 2, the printing mechanism 50 is provided with a carriage 53 which is driven by timing belt 51 suspended in a loop shape in left and right directions to reciprocate in the right and left direction along a guide 52. The carriage 53 is provided with a sheet end detecting sensor 57 which detects the upper, lower, right, and left ends of the paper sheet P. That is, the sheet end detecting sensor 57 is capable of detecting the right and left ends of the paper sheet P to recognize the width of the paper sheet P or detecting the rear end of the paper sheet P during the printing process to recognize the length of the paper sheet P, when the carriage 53 scans the paper sheet P fed to the sheet feeding port 58 the right and left directions before the printing process.

Ink cartridges 54 individually containing colors such as cyan, magenta, yellow, and black are mounted on the carriage 53. The ink cartridges 54 are connected to a printing head 55. In addition, the printing head 55 ejects ink from nozzles (not shown) onto the paper sheet P by pressurizing ink from the ink cartridges 54. In this embodiment, the printing head 55 employs a method of pressurizing the ink with application of voltage to a piezoelectric element and deforming the piezoelectric element to pressurize the ink, but may employ a method of applying voltage to a heating resistant member (for example, a heater) and heating the ink to pressurize the ink by bubbles. The paper sheet P subjected to the printing process is transported to the opened front door (sheet discharging tray) 14 by a transport roller 56.

Even though not shown in the drawing, a battery pack is configured to be mounted in the rear surface of the printer body 12 to allow the battery pack to operate the photo printer 10 without connecting the photo printer 10 to a commercial power source. The photo printer 10 is able to be carried with ease and used anywhere, since the photo printer 10 is operated by the battery back and used as a stand-alone printer which does not need to be connected to a host computer.

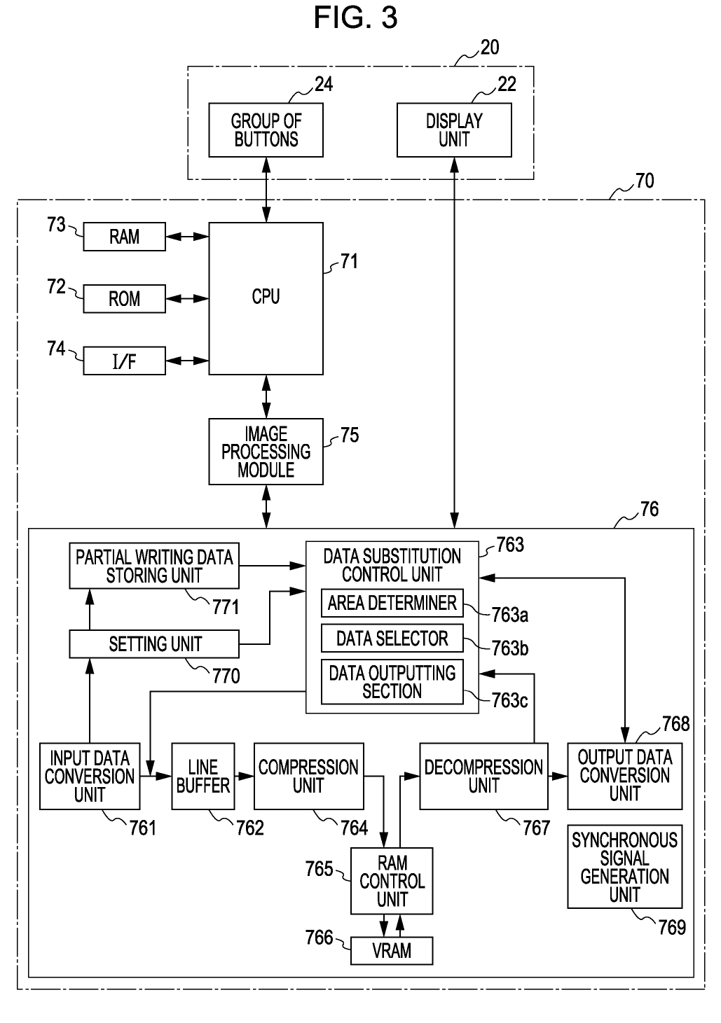

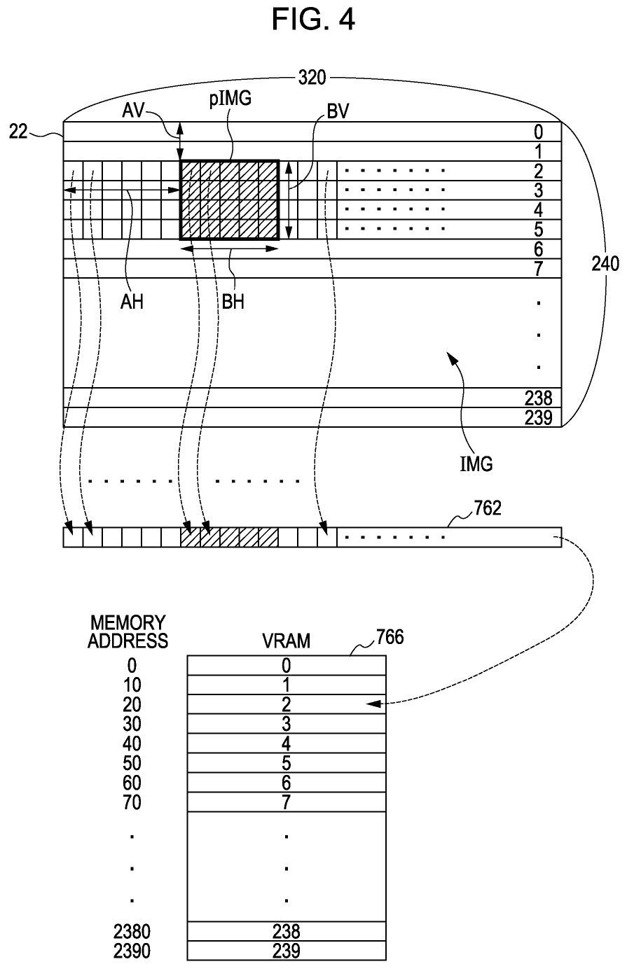

FIG. 3 is a block diagram illustrating a configuration example of the controller 70. FIG. 4 is a conceptual diagram illustrating a partial rewriting of image data. As shown in FIG. 3, the controller 70 is configured as micro processor operated mainly by a CPU 71 and includes a ROM 72 which stores various processing programs, various data, various programs, various tables, and the like, a RAM 73 which temporarily stores data, and an interface (I/F) 74 which enables the printing mechanism 50 and the memory card slot 16 to communicate with each other. In addition, the controller 70 stores an edited image or the like to the memory card M and outputs a control signal to the printing head 55 of the printing mechanism 50 or a control signal to the display unit 22 of the operational panel.

The controller 70 is provided with an image processing module 75 which performs necessary image processing on image data supplied from an external storage medium such as the memory card M through the interface 74. The image processing module 75 has a function of generating image data corresponding to an image proper to a printer, such as a menu screen, for displaying the image data on the display unit 22 or generating a partial writing data such as an icon corresponding to a partial image replaced with a part of a base image displayed on the display unit 22.

RGB image data output from the image processing module 75 are supplied to the LCD controller 76 (corresponding to “a screen display control device” according to the invention) which controls displaying of the display unit 22. Hereinafter, the display unit 22 configured by an LCD display has pixels of 320 dots×240 dots of a QVGA (Quarter Video Graphics Array) mode. One line of image data is formed by image data corresponding to 320 dots and one image is formed by line data corresponding to 240 lines (see FIG. 4). Accordingly, the RGB image data of a base image IMG corresponding one screen of the display unit 22 having the pixels of 320 dots×240 dots or RGB partial writing data of a partial image pIMG are input from the image processing module 75 to the LCD controller 76.

The LCD controller 76 includes a synchronous signal generation unit 769 which generates horizontal and vertical synchronous signals for controlling timing at which an image is displayed on the display unit 22 and various synchronous signals. In addition, the LCD controller 76 includes an input data conversion unit 761 which converts serial data input from the image processing module 75 into parallel data and a line buffer 762 which temporarily maintains one-line data of the image data converted into the parallel data by the input data conversion unit 761. In addition, the LCD controller 76 includes a compression unit 764 which is provided on the rear end of the line buffer 762 and compresses the input image data in a line unit, a rewritable VRAM 766 (corresponding to “an image memory” according to the invention) to which the compressed data compressed in a line unit by the compression unit 764 are written in non-synchronization with a reading process, a decompression unit 767 which decompresses the compressed data read in a line unit from the VRAM 766 in synchronization with the horizontal and vertical synchronous signals of the screen display on the display unit 22 to restore the compressed data to an original image data, and an output data conversion unit 768 which performs data conversion to output the image data decompressed and restored by the decompression unit 767 onto the display unit 22. With such a configuration, the image data decompressed and restored by the decompression unit 767 are output and displayed onto the display unit 22 through the output data conversion unit 768.

The LCD controller 76 includes a partial writing data storage unit 771 which maintains the partial writing data, when the partial writing data of the partial image pIMG such as an icon to be displayed on the display unit 22 are input from the image processing module 75 to the input data conversion unit 761 by replacing a part of the base image IMG stored as the compressed data to the VRAM 766. In addition, the LCD controller 76 includes a setting unit 770 which maintains coordinate information on a relative location with respect to the base image IMG of the input partial image pIMG. Information indicating with which part of the base image IMG the input partial image pIMG is replaced is stored in advance in the setting unit 770 according to this embodiment. That is, as shown in FIG. 4, there are stored in advance four kinds of coordinate information: AV indicating in which numbered line of the base image IMG a pixel on the upper left corner of the partial image pIMG is located, AH indicating to which numbered pixel the pixel on the upper left corner of the partial image pIMG correspond from a head pixel of a line of the base image IMG, BV indicating the number of lines of the partial image pIMG, and BH indicating the number of pixels of each line of the partial image pIMG.

As shown in FIG. 4, the VRAM 766 at least has an area where the compressed data of 240 lines (corresponding to one image) compressed by the compression unit 764 are stored. In this embodiment, the compressed data of lines 0, 1, 2, . . . , and 239 are stored in storage areas indicated by memory addresses 0, 10, 20, . . . , and 2390 of the VRAM 766, respectively. The LCD controller 76 also includes a RAM control unit 765 which controls a process of writing the compressed data to the VRAM 766 and processes of writing and reading the image data to and from the line buffer 762. Compression of the one-line image data stored in the line buffer 762 and timing at which the compressed data is written to the VRAM 766 are controlled. In this embodiment, the compression unit 764 is configured to compress the image data using difference information (accord status) of adjacent image data. Accordingly, the compressed data of each line are decompressed and restored in succession from pixel data at the head of each line. A method of compressing image data is not limited thereto, but known various compression methods may be used. Since the method of compressing image data is a known technique, detailed description is omitted.

The LCD controller 76 also includes a data replacement control unit 763 which replaces a portion corresponding to the partial image pIMG in the image data of the base image IMG restored by the decompression unit 767 with the partial writing data in a line unit to output the replaced partial writing data to the compression unit 764 in the line unit. The data replacement control unit 763 will be described in detail. As shown in FIG. 3, the data replacement control unit 763 includes an area determiner 763a which determines whether pixel data constituting the image data of the restored base image IMG are replaced with the partial writing data of the partial image pIMG maintained by the partial writing data storage unit 771 on the basis of the coordinate information (AV, AH, BV, and BH) input from the setting unit 770. The area determiner 763a determines whether the pixel data read from the VRAM 766 and restored by the decompression unit 767 corresponds (belongs) to a scope (area) of the base image IMG obtained from the four kinds of coordinate information described above (see FIG. 4).

The LCD controller 76 also includes a writing line counter (not shown), a reading line counter (not shown), a writing pixel counter (not shown), and a reading pixel counter (not shown), which are configured by a memory or the like. In addition, the area determiner 763a determines whether the pixel data constituting the base image IMG are replaced with the partial writing data of the partial image pIMG by comparing a counter value (reading line) of the reading line counter (not shown) to the coordinate information (AV and BV) and comparing a value (read pixel) of the reading pixel counter (not shown) to the coordinate information (AH and BH). The value of the reading pixel counter is added on the basis of a clock signal generated by the synchronous signal generation unit 769 in order to specify timing at which compressed one-pixel data are read from the VRAM 766. In addition, the value of the writing pixel counter is added, whenever one-pixel data are written from compressed one-line data compressed by the compression unit 764 to the VRAM 766. In addition, the reading pixel counter is reset to “0” upon outputting the horizontal synchronous signal and the reading pixel counter is added whenever a clock signal specifying the timing at which the compressed one-pixel data generated by the synchronous signal generation unit 769 are read. Accordingly, when the horizontal synchronous signal is output, a process of adding the reading pixel counter from “0” is also started.

The data replacement control unit 763 also includes a data selector 763b which selects the pixel data to be output to the compression unit 764 from one of the image data of the restored base image IMG and the partial writing data of the partial image pIMG depending on a result determined by the area determiner 763a. The data output section 763c outputs the pixel data selected by the data selector 763b to the line buffer 762. That is, the partial writing data of the partial image pIMG are input from the partial writing data storage unit 771 to the data replacement control unit 763, the restored image data of the base image IMG are input from the decompression unit 767 to the data replacement control unit 763, and the partial writing data and the restored image data are selectively output to the compression unit 764 through the line buffer 762. In addition, when the one-line image data are stored in the line buffer 762, a command for storing the image data stored in the line buffer 762 to the VRAM 766 is issued from the data replacement control unit 763 to the RAM control unit 765. Then, after the one-line image data stored in the line buffer 762 are compressed by the compression unit 764, the compressed image data are stored in a predetermined area of the VRAM 766.

Next, a partial rewriting process on the image data will be described with reference to FIG. 4. In this embodiment, whenever the synchronous signal generation unit 769 generates the vertical synchronous signal in a period of 1/60 second and outputs the vertical synchronous signal, the compressed data corresponding to one screen which are stored in the VRAM 766 are read and restored by the decompression unit 767 to be displayed on the display unit 22. In addition, when synchronous signal generation unit 769 outputs the horizontal synchronous signal, the compressed one-line data are read from the VRAM 766. In this case, as described above, the compressed one-line data are restored in succession from the pixel data at the head of each line and the restored pixel data are sequentially output to the data replacement control unit 763. In addition, the area determiner 763a determines whether the image (pixel) data output from the decompression unit 767 are replaced with the partial writing data of the partial image pIMG stored in the partial writing data storage unit 771 on the basis of the coordinate information (AV, AH, BV, and BH) of the partial image pIMG maintained by the setting unit 770.

That is, the area determiner 763a determines whether each of pixel data from a head pixel data (on upper left corner) of a zeroth line, which is read from the VRAM 766, restored by the decompression unit 767, and output to the data replacement control unit 763, to final pixel data (on lower right corner) of a 239th line are replaced in succession with the partial writing data. In the example shown in FIG. 4, the image data of the zeroth line are determined in succession from the head pixel data by the area determiner 763a. Since a portion corresponding to the partial image is not present in the zeroth line, the pixel data are output to the line buffer 762 in succession from the head pixel data by the data output section 763c to be temporarily stored. Subsequently, when the one-line image data (of the zeroth line) are maintained in the line buffer 762, the command is issued to the RAM control unit 765, the image data maintained in the line buffer 762 are compressed by the compression unit 764, and then the compressed image data are stored in an area of the memory address 0 of the VRAM 766, which is an area where the compressed image data of the zeroth line are stored.

Subsequently, the same process is performed on the image data of a first line. In addition, since some of the image data of the second line correspond to the partial image, the image data of a second line are processed as follow. That is, the image data are determined in succession from a head pixel data by the area determiner 763a on the basis of the coordinate information AH. Depending on the determination result, the data output section 763c outputs the image data selected by the data selector 763b to the line buffer 762. At this time, as indicated by an oblique line in FIG. 4, the data selector 763b selects the partial writing data for a portion corresponding to the partial image pIMG in the image data of the base image IMG. Then, the partial writing data are maintained in the line buffer 762. In addition, when the one-line image data (of the second line) are maintained in the line buffer 762, the command is issued to the RAM control 765, the image data maintained by the line buffer 762 are compressed by the compression unit 764, and then the compressed image data are stored in an area of the memory address 20 of the VRAM 766, which is a storage area of the compressed data of the second line. Subsequently, by performing the same process from a third line to the 239th line, the compressed data for an image in which some of the image data of the base image IMG are replaced with the partial writing data of the partial image pIMG are stored in the VRAM 766. In addition, by reading and decompressing the compressed data stored in the VRAM 766, an image in which a part of the base image IMG is replaced with the partial image pIMG is displayed on the display unit 22.

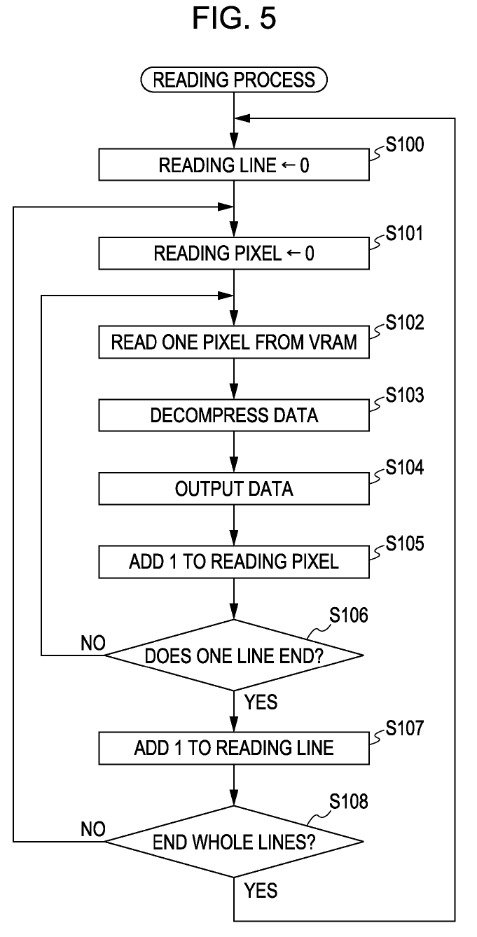

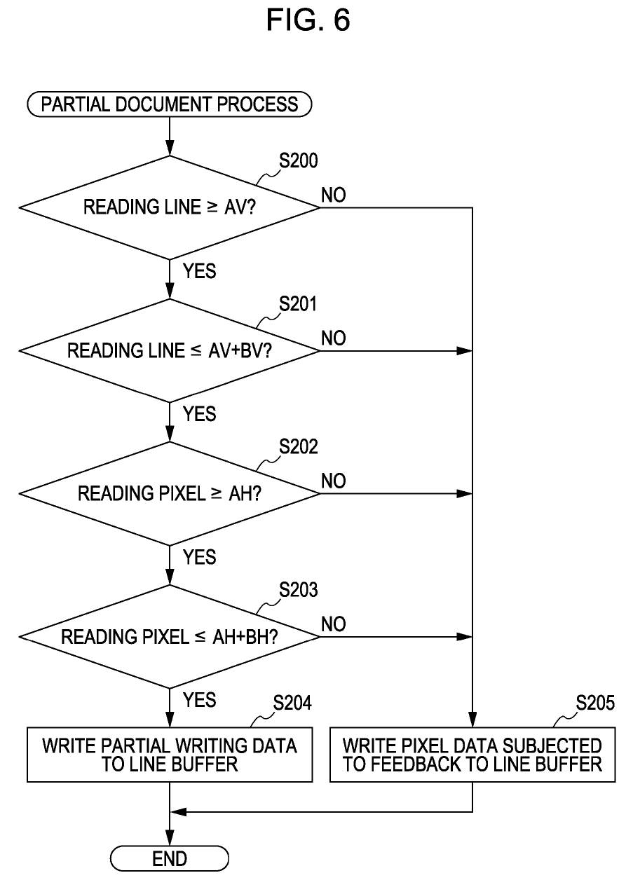

In this embodiment, the partial writing data of the partial image pIMG are configured to be input from the image processing module 75 to the input data conversion unit 761. However, the partial image pIMG such as an icon may be maintained in advance in the partial writing data storage unit 771. In addition, in this embodiment, the coordinate information on the relative location of the partial image pIMG with respect to the base image IMG is maintained in advance in the setting unit 770. However, for example, the partial writing data in which the coordinate information is contained in a header may be output from the image processing module 75 to the input data conversion unit 761. With such a configuration, the setting unit 770 is able to acquire and maintain the coordinate information from the header of the input partial writing data. Next, examples of the reading process and the partial rewriting process on the image data of the base image IMG will be described with reference to FIGS. 5 and 6.

### Reading Process

FIG. 5 is a diagram illustrating an example of the reading process of reading the compressed data from the VRAM 766 to restore the image data. The reading process in FIG. 5 is a process performed in synchronization with the vertical synchronous signal output every 1/60 second by the synchronous signal generation unit 769. In addition, the process of reading the compressed data of each line from the VRAM 766 is performed in synchronization with the horizontal synchronous signal output by the synchronous signal generation unit 769. First, when the vertical synchronous signal is output from the synchronous signal generation unit 769, the counter value (reading line) of the reading line counter constituted by a memory or the like is set to “0” (Step S100). In addition, when the horizontal synchronous signal is output from the synchronous signal generation unit 769, the counter value (reading pixel) of the reading pixel counter constituted by a memory or the like is set to “0” (Step S101). The reading line which is the counter value of the reading line counter refers to a value indicating a line number of the compressed data to be read from the VRAM 766. The reading pixel which is the counter value of the reading pixel counter refers to a value added whenever the compressed pixel data for one pixel is read from compressed pixel data at the head of the compressed pixel data (320 data) constituting the compressed one-line data and refers to a value indicating which numbered pixel data from the head of the compressed pixel data is read to be restored.

Next, one compressed pixel data indicated by the reading line and the reading pixel is read from the VRAM 766 in Step S102, and the read pixel data is decompressed and restored by the decompression unit 767 (Step S103). Subsequently, the restored image (pixel) data in Step S103 is output to the output data conversion unit 768 (Step S104). Then, one is added to the counter value of the reading pixel counter (Step S105), and then it is determined whether the process of reading the compressed data of one line ends (Step S106).

When NO is determined in Step S106, the processes from Step S102 are repeatedly performed until the process of reading the compressed one-line data ends. Alternatively, when YES is determined in Step S106, one is added to the counter value of the reading line counter (Step S107). Then, it is determined whether the process of reading the compressed data of the whole lines ends in Step S108. When YES is determined in Step S108, the process proceeds to Step S100. When a subsequent vertical synchronous signal is output, the process from Step S100 is performed. Alternatively, when NO is determined in Step S108, the processed from Step S101 are repeatedly performed until the process of reading the compressed data of the whole lines ends.

### Partial Rewriting Process

FIG. 6 is a diagram illustrating an example of the partial rewriting process performed by the data replacement control unit 763. In the partial rewriting process, it is determined whether the image (pixel) data of the base image IMG which are restored by the decompression unit 767 and feedbacked to the data replacement control unit 763 are replaced with the partial writing data of the partial image pIMG. Specifically, on the basis of the coordinate information (AV, AH, BV, and BH) of the partial image pIMG input from the setting unit 770, it is determined whether the feedbacked image (pixel) data of the base image IMG is the portion corresponding to the partial image pIMG (Steps S200 to S203, see FIG. 4). When No is determined and thus it is determined that the feedbacked image (pixel) data is not replaced with the partial writing data, that is, when NO is determined in one of the processes of Steps S200 to S203, the data selector 763b selects the feedbacked image (pixel) data and the data output section 763c the selected image (pixel) data to the line buffer 762 (Step S205). Alternatively, when YES is determined in all the processes of Steps S200 to S203 and thus it is determined that the feedbacked image (pixel) data is replaced with the partial writing data, the data selector 763b selects the partial writing data and the data output section 763c outputs the selected partial writing data to the line buffer 762 (Step S204).

In this embodiment, as described above, the portion corresponding to the partial image pIMG in the image data of the base image IMG read from the VRAM 766 and restored by the decompression unit 767 is replaced with the partial writing data by the data replacement control unit 763, and then the replaced partial writing data are compressed by the compression unit 764 and stored in the VRAM 766. In addition, an image in which the part of the base image IMG is replaced with the partial image pIMG is displayed on the display unit 22 in such a manner that the compressed data of which some are replaced with the partial writing data are read from the VRAM 766 and restored by the decompression unit 767. Since the image data are partially rewritable with only the partial writing data of the partial image pIMG by using the image data of the base image IMG obtained by restoring the compressed data stored in the VRAM 766, it is possible to replace the part of the base image IMG with the partial image pIMG in a very efficient manner.

Since a large volume of image data is divided into data in a line unit to be processed, it is possible to simplify the processes such as compression and decompression.

Moreover, since the area determiner 763a determines whether the pixel data constituting the image data of the base image IMG are replaced with the partial writing data of the partial image pIMG on the basis of the coordinate information (AV, AH, BV, and BH) maintained in the setting unit 770 and the data selector 763b selects the data to be output to the compression unit 764 from one of the restored image data and partial writing data depending on the determination result, it is possible to exactly replace the portion corresponding to the partial image pIMG in the image data of the base image IMG with the partial writing data.

### MODIFIED EXAMPLE

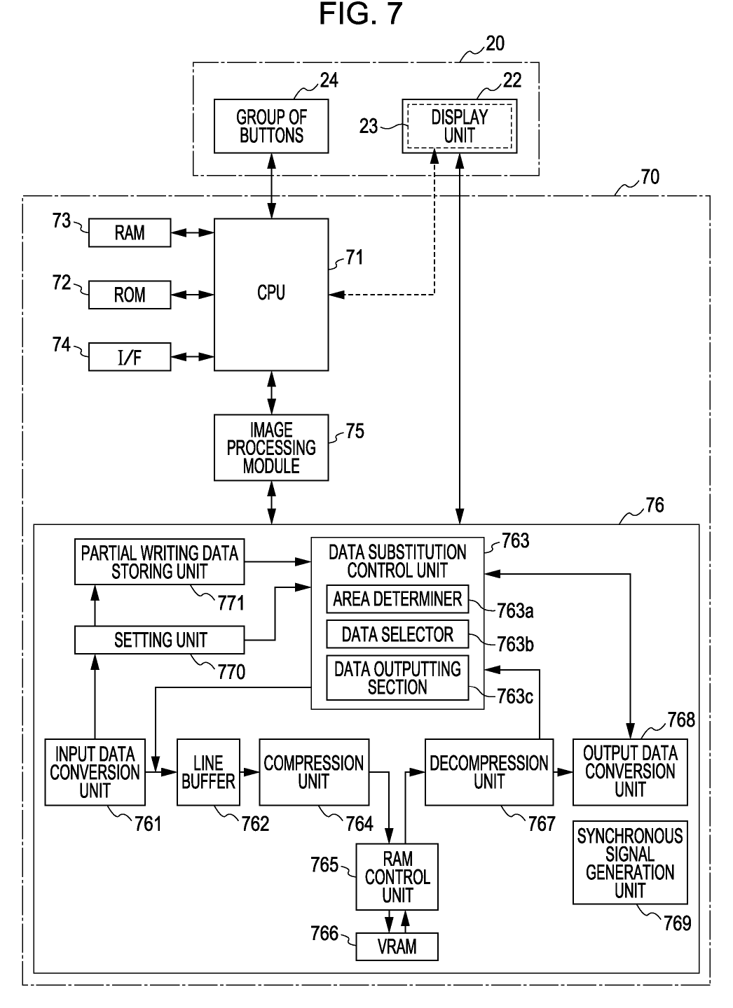

FIG. 7 is a block diagram illustrating another example of the configuration of the controller 70. A configuration in which a user is able to arbitrarily input a location rewritten to the partial image pIMG in the base image IMG will be described with reference to FIG. 7. As shown in FIG. 7, a different point between this modified example and the above-described embodiment is that a touch panel 23 is provided in the display unit 22 and the user is able to directly input a location replaced with the partial image pIMG in the base image IMG displayed on the display unit 22 using the touch panel 23. In the modified example, a portion to be replaced is the location of the base image IMG designated by the touch panel 23. For example, partial writing data of a partial image pIMG having a “” shape are stored in the partial writing data storage unit 771 and only coordinate information is input to the LCD controller 76 by the touch panel 23, as described below. However, as described above, the partial writing data and the coordinate information input by the touch panel 23 may be input from the image processing module 75 to the LCD controller 76. Of course, the partial pIMG to be replaced is arbitrary. Hereinafter, the configuration of the touch panel 23 and a partial rewriting process on the base image IMG using the touch panel 23 will be described.

The touch panel 23 formed of a transparent and semi-transparent member is provided integrally with the display unit 22 or attached to a display screen of the display unit 22 so that the user is able to recognize an image to be displayed on the display unit 22. When the user touches the touch panel 23 with a prepared pen or the like, viewing an image such as the base image IMG displayed on the display unit 22, signals indicating coordinates on the touch panel 23 touched with the pen are output to the CPU 71. Therefore, when the user intends to rewrite an arbitrary location of the base image IMG displayed on the display unit 22 to the partial image pIMG, the user touches the arbitrary location of the touch panel 23 provided with the substantial same size in an overlapped manner on the display screen of the display unit 22 in a state where the base image IMG is displayed on the display unit 22. In this way, the user is able to input the arbitrary location to be rewritten to the partial image pIMG in the base image IMG to the CPU 71.

When the controller 70 inputs the coordinate information based on the signals input from the touch panel 23 to the CPU 71 to the LCD controller 76 through the image processing module 75, the input data conversion unit 761 outputs the input coordinate information to the setting unit 770. Then, on the basis of the coordinate information input to the setting unit 770 and predetermined partial writing data stored in advance in the partial writing data storage unit 771, an image having coordinates designated by the touch panel 23 in the base image IMG and replaced to the partial image pIMG is displayed on the display unit 22 in the same processes as those described above in the embodiment.

Subsequently, when the user moves the pen or the like on the touch panel 23, viewing the image displayed on the display unit 22, signals indicating coordinate moved on the touch panel 23 by the pen continue to be output to the CPU 71 and the LCD controller 76 continues to replace the base image IMG with the partial image pIMG on the basis of the coordinate information. Therefore, when the user moves the pen on the touch panel 23, viewing the base image IMG displayed on the display unit 22, the user is able to picture an arbitrary image on the base image IMG by loci of the partial image pIMG.

The user is able to easily picture an arbitrary image such as a text or a figure on the base image IMG with a simple configuration by employing the touch panel 23 in the configuration in which the compressed image data described in the embodiment are partially rewritten. In addition, various types such as an optical type, a capacitance type, a type using transparent electrodes and a film substrate, a resistive type, and a surface acoustic wave type are employed in the touch panel 23. Since the various types are known, description of the configuration and operation thereof is omitted. Even when a so-called pen type input device is employed instead of the touch panel 23, the same advantage is obtained. Of course, instead of the touch panel 23, any input device may be employed as long as the user directly instructs the location of the base image IMG displayed on the display 22 in visual manner.

The invention is not limited to the above-described embodiment, but may be modified in various forms without departing the gist of the invention. For example, in the above-described embodiment, the image data are usually stored in the line buffer 762, the image data are compressed in a line unit by the compression unit 764, the image data of the base image IMG are replaced with the partial writing data in the line unit. However, the above-described processes may be performed in a unit of one-screen image data without providing the line buffer 762. Moreover, the partial writing data storage unit 771 and the line buffer 762 may be configured by the same memory to realize a simple configuration.

In the above-described embodiment, the ink cartridge type photo printer 10 is described as an example, but the invention may be applied to printing apparatuses such as other ink jet printers. Moreover, the invention is able to be widely applied to techniques for displaying an image on a screen display device such as a liquid crystal display, a plasma display, and an organic EL display.

What is claimed is:

1. A screen display control device comprising:
a compression unit which compresses input image data of a one-screen base image;
a rewritable image memory to which the compressed data compressed by the compression unit is written in non-synchronization with a reading process;
a decompression unit which decompresses the compressed data periodically read from the image memory in synchronization with screen display to restore original image data;
a display unit which displays an image of the image data decompressed and restored by the decompression unit;
a partial writing data storage unit which maintains partial writing data of a partial image to be displayed on the display unit by replacing a part of the base image; and
a data replacement control unit which replaces a portion corresponding to the partial image in the image data of the base image restored by the decompression unit with the partial writing data to output the partial writing data to the compression unit.

2. The screen display control device according to claim 1,
wherein the compression unit compresses the input image data in a line unit,
wherein the decompression unit decompresses and restores the compressed data periodically read from the image memory in the line unit in synchronization with screen display, and
wherein the data replacement control unit replaces the image data of the base image restored by the decompression unit with the partial writing data in the line unit to output the partial writing data to the compression unit.

3. The screen display control device according to claim 1, further comprising a setting unit which maintains coordinate information on a relative location with respect to the base image of the partial image,
wherein the data replacement control unit includes:
an area determiner which determines whether each pixel data constituting the restored image data is replaced with the partial writing data on the basis of the coordinate information input from the setting unit; and
a data selector which selects data to be output to the compression unit from one of the restored image data and the partial writing data depending on a result determined by the area determiner.
